(19) United States
(12) Patent Application Publication
(10) Pub. No.: US 2026/0319039 A1
(43) Pub. Date: Oct. 15, 2026

(54) INTERNAL BABY VACUUM CHAMBER AS CRYO-PUMP TO ADSORB OUTGASSING AFTER MAGNET QUENCH

(71) Applicant: GE Precision Healthcare LLC, Waukesha, WI (US)

(72) Inventors: Anbo Wu, Clifton Park, NY (US); Ernst Wolfgang Stautner, Niskayuna, NY (US); Vijay Kumar Soni, Niskayuna, NY (US)

(21) Appl. No.: 19/174,473

(22) Filed: Apr. 9, 2025

(51) Int. Cl. G01R 33/38; G01R 33/3815; H10N 60/83

(52) U.S. Cl. CPC G01R 33/3804; G01R 33/3815; H10N 60/83

(57) ABSTRACT

A superconducting machine system includes a superconducting machine that includes a composite structure. The superconducting machine system also includes a thermal shield encompassing the superconducting machine. The superconducting machine system further includes a vacuum vessel encompassing the thermal shield. The superconducting machine system still further includes a vacuum chamber encompassed by the thermal shield, wherein the vacuum chamber is configured to act as a cryo-pump to adsorb outgassing gases released from the superconducting machine and the composite structure during a quench event.

### BACKGROUND

The subject matter disclosed herein relates to utilizing an internal baby vacuum chamber as a cryo-pump to adsorb outgassing after a magnet quench.

Non-invasive imaging technologies allow images of the internal structures or features of a patient/object to be obtained without performing an invasive procedure on the patient/object. In particular, such non-invasive imaging technologies rely on various physical principles (such as the differential transmission of X-rays through a target volume, the reflection of acoustic waves within the volume, the paramagnetic properties of different tissues and materials within the volume, the breakdown of targeted radionuclides within the body, and so forth) to acquire data and to construct images or otherwise represent the observed internal features of the patient/object.

During magnetic resonance imaging (MRI), when a substance such as human tissue is subjected to a uniform magnetic field (polarizing field B₀), the individual magnetic moments of the spins in the tissue attempt to align with this polarizing field, but precess about it in random order at their characteristic Larmor frequency. If the substance, or tissue, is subjected to a magnetic field (excitation field B1) which is in the x-y plane and which is near the Larmor frequency, the net aligned moment, or “longitudinal magnetization”, M_{z}, may be rotated, or “tipped”, into the x-y plane to produce a net transverse magnetic moment, Mₜ. A signal is emitted by the excited spins after the excitation signal B₁ is terminated and this signal may be received and processed to form an image.

When utilizing these signals to produce images, magnetic field gradients (Gₓ, G_{y}, and G_{z}) are employed. Typically, the region to be imaged is scanned by a sequence of measurement cycles in which these gradient fields vary according to the particular localization method being used. The resulting set of received nuclear magnetic resonance (NMR) signals are digitized and processed to reconstruct the image using one of many well-known reconstruction techniques.

Next generation MRI magnet systems are “sealed” with coil support structures made of light weight composite materials. “Sealed” means, those MRI systems come with a reduced cryogen volume of about 5 to 40 liters compared to “wet” systems that utilize 1500 liters or more. “Sealed” systems generally leave the main magnet support structure exposed to a surrounding vacuum environment whereas with “wet” systems the magnet sits in a bath of liquid helium (i.e., immersed magnet). Initially, the cryostat needs to be evacuated. The magnet coils then need to cool down to cryogenic temperatures to allow the magnet to achieve its superconducting state. After the magnet ramps to full design current, the superconducting switch is closed (becomes superconducting), and the superconducting magnet moves into a persistent state. To maintain the cryogenic temperature for the magnet a cryocooler is used. Any cryocooler may fail for many different reasons, or the cryocooler may stop due to a power outage. Even other events, like the sudden loss of vacuum or any accidents leading to the use of an emergency run down unit will make the magnet lose its superconducting state. During this event, the magnet may quench and warm up to 50 Kelvin or higher, releasing deposited gases or embedded gases, deteriorating the surrounding vacuum chamber, hereby worsening the vacuum. In this case, the magnet coils will therefore warm up quickly. As a result, cooldown back to the operating temperature is compromised and takes much longer. In that case, an external cooldown tool needs to be used to start precooling again which causes long delays at the site of the system.

### SUMMARY

A summary of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects that may not be set forth below.

In one embodiment, a superconducting machine system is provided. The superconducting machine system includes a superconducting machine that includes a composite structure. The superconducting machine system also includes a thermal shield encompassing the superconducting machine. The superconducting machine system further includes a vacuum vessel encompassing the thermal shield. The superconducting machine system still further includes a vacuum chamber encompassed by the thermal shield, wherein the vacuum chamber is configured to act as a cryo-pump to adsorb outgassing gases released from the superconducting machine and the composite structure during a quench event.

In another embodiment, a superconducting magnet system for a magnetic resonance imaging system is included. The superconducting magnet system includes a superconducting magnet coil disposed on a support structure, wherein the support structure includes a composite material. The superconducting magnet system also includes a thermal shield encompassing the superconducting magnet coil and the support structure. The superconducting magnet system further includes a vacuum vessel encompassing the thermal shield. The superconducting magnet system even further includes a vacuum chamber encompassed by the thermal shield, wherein the vacuum chamber is configured to act as a cryo-pump to adsorb outgassing gases released from the superconducting magnet coil and the support structure during a quench event.

In a further embodiment, a method for managing outgassing from a superconducting machine system is provided. The superconducting machine system includes a superconducting machine including a composite structure. The superconducting machine system also includes a thermal shield encompassing the superconducting machine. The superconducting machine system further includes a vacuum vessel encompassing the thermal shield. The superconducting machine system even further includes a vacuum chamber encompassed by the thermal shield, wherein the vacuum chamber is configured to act as a cryo-pump to adsorb outgassing gases released from the superconducting machine and the composite structure during a quench event. The vacuum chamber includes an electrical heater. The superconducting machine system also includes a plurality of sorption surfaces disposed within the vacuum chamber. The superconducting machine system further includes a first conduit coupling an internal atmosphere within the thermal shield to the vacuum chamber. The superconducting machine system even further includes a first valve disposed along the first conduit. The superconducting machine system also includes a vacuum pump located outside the vacuum vessel. The superconducting machine system further includes a second conduit coupled to the vacuum pump, the first conduit, and the vacuum chamber via the first conduit, wherein the second conduit is coupled to first conduit between the first valve and the vacuum chamber. The superconducting machine system further includes a second valve disposed along the second conduit between the vacuum pump and the vacuum chamber. Upon the quench event occurring to the superconducting machine system, the method includes: automatically opening the first valve to enable the vacuum chamber and the plurality of sorption surfaces to adsorb the outgassing gases; closing the first valve after reaching a predetermined temperature after the quench event; after closing of the first valve, utilize the electrical heater to warm up the vacuum chamber to a temperature that desorbs the outgassing gases from the plurality of sorption surfaces; and after closing of the first valve, opening the second valve to enable the vacuum pump to remove the outgassing gases from within the vacuum chamber.

### BRIEF DESCRIPTION OF THE DRAWINGS

These and other features, aspects, and advantages of the present disclosure will become better understood when the following detailed description is read with reference to the accompanying drawings in which like characters represent like parts throughout the drawings, wherein:

FIG. 1 is side, cross-sectional view of a cooling system for a magnetic resonance imaging machine, in accordance with aspects of the present disclosure;

FIG. 2 is a schematic illustration of the system of FIG. 1, shown in connection with a magnetic resonance imaging machine, in accordance with aspects of the present disclosure;

FIG. 3 is a schematic diagram of a cryogenic outgassing management system, in accordance with aspects of the present disclosure;

FIG. 4 is a schematic diagram of a cryogenic outgassing management integrated with a superconducting machine system (e.g., having a superconducting machine having a composite structure), in accordance with aspects of the present disclosure;

FIG. 5 is a schematic diagram of a cryogenic outgassing management integrated with a device having a composite structure, in accordance with aspects of the present disclosure;

FIG. 6 is a cross-sectional perspective view of a shroud of the cryogenic outgassing management system in FIG. 3, in accordance with aspects of the present disclosure;

FIG. 7 is a cross-sectional view of a superconducting magnet system having the cryogenic outgassing management system (e.g., having a shroud), in accordance with aspects of the present disclosure;

FIG. 8 is a cross-sectional view of a superconducting magnet system having the cryogenic outgassing management system (e.g., lacking a shroud), in accordance with aspects of the present disclosure; and

FIG. 9 is a flow chart of a method for managing outgassing from a superconducting machine system, in accordance with aspects of the present disclosure.

### DETAILED DESCRIPTION

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers’ specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present subject matter, the articles “a,” “an,” “the,” and “said” are intended to mean that there are one or more of the elements. The terms “comprising,” “including,” and “having” are intended to be inclusive and mean that there may be additional elements other than the listed elements. Furthermore, any numerical examples in the following discussion are intended to be non-limiting, and thus additional numerical values, ranges, and percentages are within the scope of the disclosed embodiments.

While aspects of the following discussion are provided in the context of medical imaging, it should be appreciated that the disclosed techniques are not limited to such medical contexts. Indeed, the provision of examples and explanations in such a medical context is only to facilitate explanation by providing instances of real-world implementations and applications. However, the disclosed techniques may also be utilized in other contexts, such as power generation using superconducting machines. In general, the technique can be used in all superconducting machinery and/or devices (e.g., composite-based liquid hydrogen tanks) that utilize a composite structure.

The present disclosure provides for utilizing an internal baby vacuum chamber as a cryo-pump to adsorb outgassing after a magnet quench. In particular, the internal baby vacuum chamber forms part of an outgassing management system for sealed systems. Disclosed systems and methods apply to any superconducting machine (e.g., superconducting electrical machine) or device that utilizes composite material (which are materials that outgas the most) for a lightweight design (e.g., superconducting magnet of a magnetic resonance imaging system, superconducting motor, superconducting generator, some composite cryostats, composite liquid hydrogen tanks for aircraft, etc.). The disclosed system and method enable avoiding the use of external cooldown tools in a quench event so that one or more cryocoolers themselves only can run the superconducting machine (e.g., magnet) back to operating temperature. The disclosed system and method avoid the softening of the vacuum chamber by enabling the capture (and release) of gases that position (e.g., contaminate) the vacuum.

The internal baby vacuum chamber (acting as a cryo-pump (as well as internal sorption pump) utilizing cryo-sorption effect and a vacuum different between vacuum vessel and internal baby vacuum chamber) captures outgassing gases released from the superconducting machine released from the superconducting machine surface and support structure. The disclosed systems and methods leverage a magnet cryocooler to cool the internal baby vacuum chamber. No separate cooler is needed (e.g., a regular cryo-pump). A thermal link between the internal baby vacuum chamber and second stage of the cryocooler is properly engineered to enable cooling the internal baby vacuum chamber to 5 to 15 Kelvin (K) in an equilibrium state. The warm up of the internal baby vacuum chamber is slower than the cryocooler and thermal shield after the magnet quench and out of cooling.

In certain embodiments, internal baby vacuum chamber and the superconducting machine (e.g., magnet) and its support structure (e.g., made of composite material) are shrouded which also enables capture of outgassing gases released from the superconducting machine surface and support structure. This is particularly important for any sealed MRI system since those are built to be lightweight and are based on the use of composite material (e.g., for the former which serves as the support structure). In the absence of capturing, confining, adsorbing, containing, and removing outgassing gases that occur during a quench event, the magnet will quickly warmup to room temperature. The disclosed systems and methods by avoiding poisoning of the vacuum reduce the time needed to return the magnet of the MRI system to an operating state from a couple of weeks down to a day in the case of MRI magnet fault condition, thus, significantly reducing MRI system downtime. The disclosed systems and methods improve sealed magnet serviceability. The disclosed systems and methods maintain an adequate magnet vacuum level to enable faster re-cooldown of the magnet after magnet quench. This is particularly important and beneficial to a sealed magnet without helium vessel. Removing the helium vessel of the sealed magnet can save cost and minimize MGI loss.

The disclosed embodiments include a superconducting machine system that includes a superconducting machine that includes a composite structure. The superconducting machine system also includes a thermal shield encompassing the superconducting machine. The superconducting machine system further includes a vacuum vessel encompassing the thermal shield. The superconducting machine system still further includes a vacuum chamber encompassed by the thermal shield, wherein the vacuum chamber is configured to act as a cryo-pump to adsorb outgassing gases released from the superconducting machine and the composite structure during a quench event.

In certain embodiments, the vacuum chamber is configured to utilize a difference in vacuum pressure between the vacuum vessel and the vacuum chamber in conjunction with cryo-sorption effect to adsorb the outgassing gases. In certain embodiments, the superconducting machine system includes a first conduit coupling an internal atmosphere within the thermal shield to the vacuum chamber and a first valve disposed along the first conduit. In certain embodiments, the first valve is configured to be closed prior to cooling of the superconducting machine, and the first valve is configured to be automatically opened after a quench event to enable the vacuum chamber to adsorb the outgassing gases. In certain embodiments, the vacuum chamber includes a plurality of sorption surfaces disposed within the vacuum chamber to initially adsorb the outgassing gases. In certain embodiments, the vacuum chamber includes a plurality of fins, and the plurality of sorption surfaces are disposed on the plurality of fins and/or internal wall surfaces of the vacuum chamber. In certain embodiments, the plurality of sorption surfaces includes activated carbon or advanced zeolites. In certain embodiments, the superconducting machine system includes an electrical heater disposed on the vacuum chamber, wherein the first valve is configured to be closed after reaching a predetermined temperature after the quench event, and the electrical heater, after closing of the first valve, is configured to warm up the vacuum chamber to a temperature that desorbs the outgassing gases from the plurality of sorption surfaces. In certain embodiments, the superconducting machine system includes a vacuum pump located outside the vacuum vessel; a second conduit coupled to the vacuum pump, the first conduit, and the vacuum chamber via the first conduit, wherein the second conduit is coupled to first conduit between the first valve and the vacuum chamber; and a second valve disposed along the second conduit between the vacuum pump and the vacuum chamber. In certain embodiments, the second valve is configured, after closing of the first valve, to be opened to enable the vacuum pump to remove the outgassing gases that were desorbed from the plurality of sorption surfaces.

In certain embodiments, the superconducting machine includes a superconducting magnet coil disposed on a support structure, and the support structure includes the composite structure. In certain embodiments, the superconducting machine system includes a cryocooler coupled to the vacuum vessel and the thermal shield, wherein the vacuum chamber is thermally coupled to the cryocooler via a thermal link, and the cryocooler is configured to cool the vacuum chamber. In certain embodiments, the cryocooler is configured to cool the vacuum chamber to a temperature between 5 and 15 Kelvin, and wherein the vacuum chamber is solely cooled by the cryocooler.

The disclosed embodiments include a superconducting magnet system for a magnetic resonance imaging system that includes a superconducting magnet coil disposed on a support structure, wherein the support structure includes a composite material. The superconducting magnet system also includes a thermal shield encompassing the superconducting magnet coil and the support structure. The superconducting magnet system further includes a vacuum vessel encompassing the thermal shield. The superconducting magnet system even further includes a vacuum chamber encompassed by the thermal shield, wherein the vacuum chamber is configured to act as a cryo-pump to adsorb outgassing gases released from the superconducting magnet coil and the support structure during a quench event.

The disclosed embodiments include method for managing outgassing from a superconducting machine system. The superconducting machine system includes a superconducting machine including a composite structure. The superconducting machine system also includes a thermal shield encompassing the superconducting machine. The superconducting machine system further includes a vacuum vessel encompassing the thermal shield. The superconducting machine system even further includes a vacuum chamber encompassed by the thermal shield, wherein the vacuum chamber is configured to act as a cryo-pump to adsorb outgassing gases released from the superconducting machine and the composite structure during a quench event. The vacuum chamber includes an electrical heater. The superconducting machine system also includes a plurality of sorption surfaces disposed within the vacuum chamber. The superconducting machine system further includes a first conduit coupling an internal atmosphere within the thermal shield to the vacuum chamber. The superconducting machine system even further includes a first valve disposed along the first conduit. The superconducting machine system also includes a vacuum pump located outside the vacuum vessel. The superconducting machine system further includes a second conduit coupled to the vacuum pump, the first conduit, and the vacuum chamber via the first conduit, wherein the second conduit is coupled to first conduit between the first valve and the vacuum chamber. The superconducting machine system further includes a second valve disposed along the second conduit between the vacuum pump and the vacuum chamber. Upon the quench event occurring to the superconducting machine system, the method includes: automatically opening the first valve to enable the vacuum chamber and the plurality of sorption surfaces to adsorb the outgassing gases; closing the first valve after reaching a predetermined temperature after the quench event; after closing of the first valve, utilize the electrical heater to warm up the vacuum chamber to a temperature that desorbs the outgassing gases from the plurality of sorption surfaces; and after closing of the first valve, opening the second valve to enable the vacuum pump to remove the outgassing gases from within the vacuum chamber.

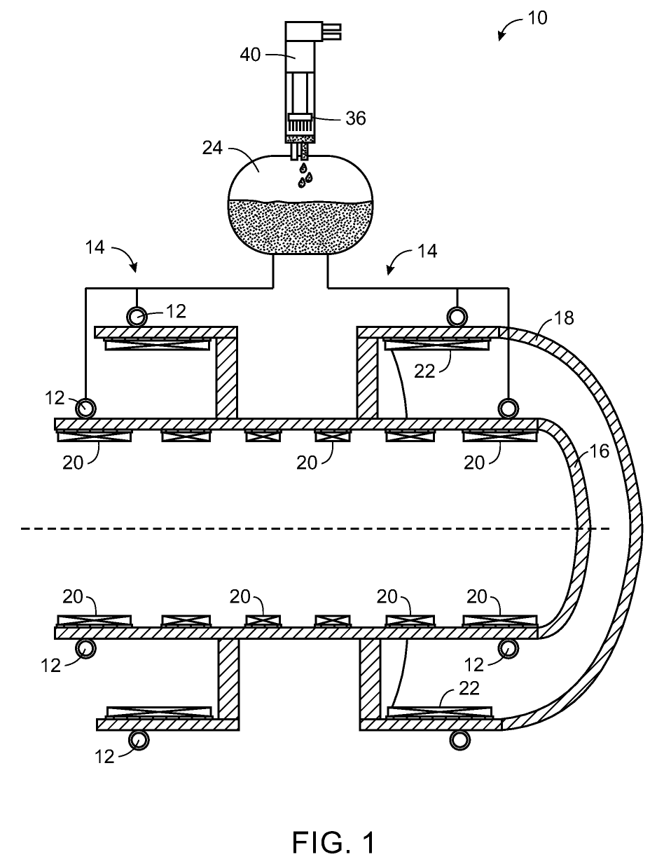

Referring now to FIG. 1, a cooling system 10 for a superconducting magnet (e.g., superconducting machine or superconducting electrical machine of a superconducting machine system) of an MRI machine (e.g., MRI system) is illustrated. As shown therein, the cooling system 10 includes a plurality of cooling tubes 12, or other suitable cooing paths, with liquid helium circulating within the cooling tubes 12. The cooling tubes 12 define a primary cooling loop 14. The cooling tubes 12 are thermally coupled to a main former or support shell 16 and, in an embodiment, may also be thermally coupled to a shield former or support shell 18 that encompasses the main former 16. The main former 16 and shield former 18 support or maintain the position of main MRI magnet coils 20 and shielding MRI magnet coils 22 (also referred to as bucking coils), respectively, in a manner heretofore known in the art. For example, the main magnet coils 20 may be shrink fit and bonded inside the main former 16, which may be a cylindrical composite former, to thereby provide thermal contact therebetween. Likewise the shield magnet coils 22 may be shrink fit and bonded inside the shield former 18, which may be a cylindrical composite former, to thereby provide thermal contact therebetween. Other types of coils may be provided, for example, epoxied coils. In an embodiment the main magnet coils 20 and the magnet shielding coils 22 may be formed from any material capable of producing a superconducting magnet, such as from Niobium-titanium (NbTi), Niobium-tin (Nb₃Sn) or Magnesium-di-boride (MgB₂) or any other type of high temperature superconductor.

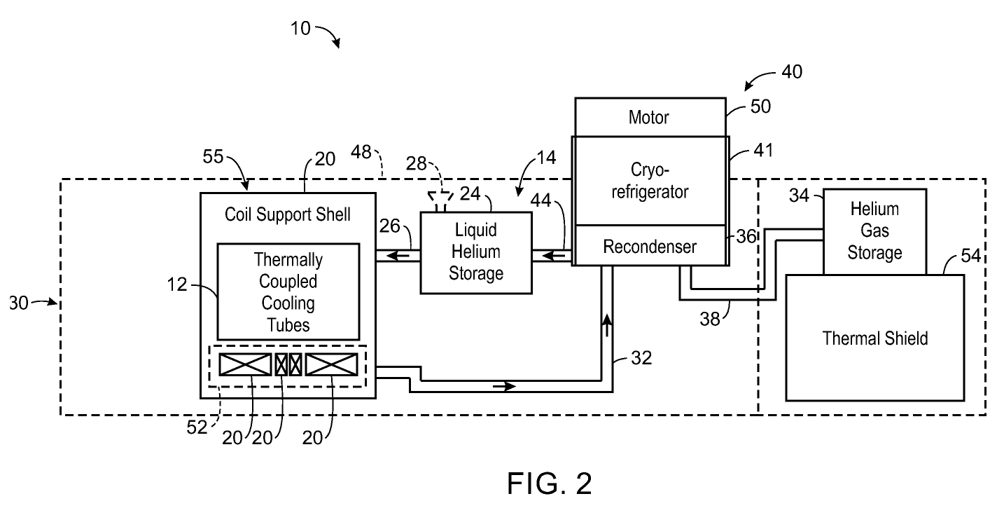

As further illustrated in FIG. 2, the various embodiments of the present invention may be implemented as part of an MRI magnet system 30, such as those commonly known in the art, wherein the cooling may be provided via a two stage cooling arrangement.

The coil formers 16, 18, which may be formed from a thermally conductive composite material, provide a cold mass support structure that maintain the position of or support the magnetic coils 20, 22, respectively (shielding magnet coils 22 not shown in FIG. 2). The coil formers 16, 18 may also be made of a composite material to make the structure lighter. The cooling tubes 12, which may be formed from any suitable metal (e.g., copper, stainless steel, aluminum, etc.) are in fluid communication with a primary, or first, liquid cryogen storage tank 24. The cryogen storage tank 24 contains a first liquid cryogen used in the closed loop cooling system 10 to cool the cold mass 55, including magnet coils 20, 22. In an embodiment, the cryogen is liquid helium. The fluid communication between the cooling tubes 12 and the liquid cryogen storage tank(s) (e.g., liquid helium storage tank(s)) 24 may be provided by one or more fluid passageways 26 (e.g., fluid tubes, conduits, etc.). Thus, the storage tank 24 provides the liquid helium that flows through the cooling tubes 12 to cool the magnet coils 20, 22.

Collectively, the assembly of magnet coils 20 and/or 22, the coil formers/support structure 16 and/or 18 and the cryogen reservoir 24 form a cold mass 55. As discussed in detail below, this cold mass 55 is cooled to target temperature. As used herein, “target temperature” means a cryogenic temperature sufficient to enable superconducting operation. In an embodiment, the target temperature is approximately 4 K. As used herein “cold mass” means any structure that is cooled to the target temperature during normal operation via the primary cooling loop 14.

In the illustrated embodiment, the primary cooling loop 14 contains no venting. However, in some embodiments, venting may be provided, for example, using a vent 28 having a very high venting pressure level. For example, in some embodiments the vent 28 is configured to provide venting at the highest pressure the system can handle without failure (or within a predefined range thereof). However, different pressure levels may be provided in embodiments that include the vent 28, which may be based on system requirements, regulatory requirements, etc.

As best illustrated in FIG. 2, in an embodiment, the cooling tubes 12 may be in fluid communication with a vapor return manifold or passageway 32, which may be in fluid communication with a helium gas storage system having a decoupled gaseous helium storage tank 34 through a recondenser 36. The helium gas storage system, which may be formed from one or more helium gas storage tanks 34 contains helium gas received as helium vapor from the cooling tubes 12 that removes heat from the magnet coils 20, 22 and forms part of the closed loop cooling system. The fluid communication between the recondenser 36 and the helium gas storage system 34 may be provided via one or more passageways 38. In certain embodiments, instead of helium, another cryogen may be utilized for cooling.

The helium gas storage tanks 34 are in fluid communication with a cryorefrigerator 40 that includes the recondenser 36, which fluid communication may be provided via one or more fluid passageways 38. In various embodiments, the recondenser 36 may draw helium gas from the helium gas storage system 34 that operates to form a free convection circulation loop to cool the magnet coils 20, 22 and coil support shells 16, 18 to a cryogenic temperature, as well as fills the reservoir 24 with liquid helium via one or more passageways 44.

The cryorefrigerator 40, which may be a coldhead or other suitable cryocooler, extends through a cryostat and/or vacuum vessel 48 which contains therein the MRI magnet system 30 and the cooling components of the various embodiments. The cryorefrigerator 40 may extend within a sleeve or housing, referred to as coldhead sleeve 41. Thus, the cold end of the cryorefrigerator 40 may be positioned within the sleeve 41 without affecting the vacuum within the vacuum vessel. The cryorefrigerator 40 is inserted (or received) and secured within the sleeve using any suitable means, such as one or more flanges and bolts, or other suitable means. Moreover, a motor 50 of the cryorefrigerator 40 is provided outside the vacuum vessel and/or cryostat 48.

As illustrated in FIG. 2, the cryorefrigerator 40 in various embodiments includes the recondenser 36 at a lower end of the cryorefrigerator 40 that recondenses boiled off helium gas received from the vapor return manifold/passageway 32 in parallel with the helium gas storage system 34. The recondenser 36 allows for transferring boiled off helium gas from the helium gas storage system 34 to the liquid helium reservoir 24.

The magnet coils 20, which in various embodiments are molded coils, form a main superconducting magnet 52 that is controlled during operation of the MRI system as is known in the art to acquire MRI image data. Additionally, during operation of the MRI system, liquid helium travelling through the thermally coupled cooling tubes 12 cools the superconducting magnet 52. The superconducting magnet 52 may be cooled, for example, to a superconducting temperature, such as 4.2 Kelvin (K). The cooling process may include the recondensing of boiled off helium gas to liquid by the recondenser 36 and returned to the liquid helium tank 24, as well as cooling of the boiled off helium.

The various embodiments also provide a thermal shield 54, which may be in thermal contact with the helium gas storage system 34. The thermal shield 54 may be, for example, a thermally isolating radiation shield.

In an embodiment, rather than cooling via the circulation of liquid helium through cooling tubes that are thermally connected to the magnet or support shell, cooling may be provided by immersing the superconducting magnet coils in a bath of liquid helium, as is known in the art. In various embodiments, once cooled to operating temperature, the magnet coils may be cooled by thermal conduction and/or by thermosiphoning cooling. As will be readily appreciated, however, whether cooling is effected through the circulation of a liquid cryogen through a cooling loop that is in thermal communication with the magnet, or through the immersion of magnet coils in a bath of liquid cryogen, the coil formers/support structure, magnet coils and/or liquid cryogen reservoir form a cold mass 55 having a temperature of approximately 4.2 K, which provides for superconducting operations. As described in greater detail below, a cryogenic outgassing management system may be provided that may be utilized in response to a quench event to minimize outgassing of the lightweight composite coil formers (and magnet) so cooldown time after the quench is minimized. In certain embodiments, outgassing management occurs in sealed, non bath-cooled systems.

Although described in the context of a superconducting magnet for an MRI system, the superconducting machine system (for which the cryogenic outgassing management system is utilized) is a superconducting generator or motor, or other type of superconducting system, such as in accelerator magnet technology, for superconducting RF cavity, or other. The cryogenic outgassing management system may also be utilized with composite cryostats, composite liquid hydrogen tanks, and other devices that utilize composite structures. The disclosed systems and methods may also be utilized with applications where a cryocooler is directly mounted onto a superconducting coil with no helium involved for cooling (i.e., conduction cooled systems or sealed systems, or completely dry systems).

It should be noted that although some embodiments may be described in connection with superconducting magnets for MRI systems, the various embodiments may be implemented in connection with any type of system having superconducting magnets. The superconducting magnets may be implemented in other types of medical imaging devices, as well as non-medical imaging devices.

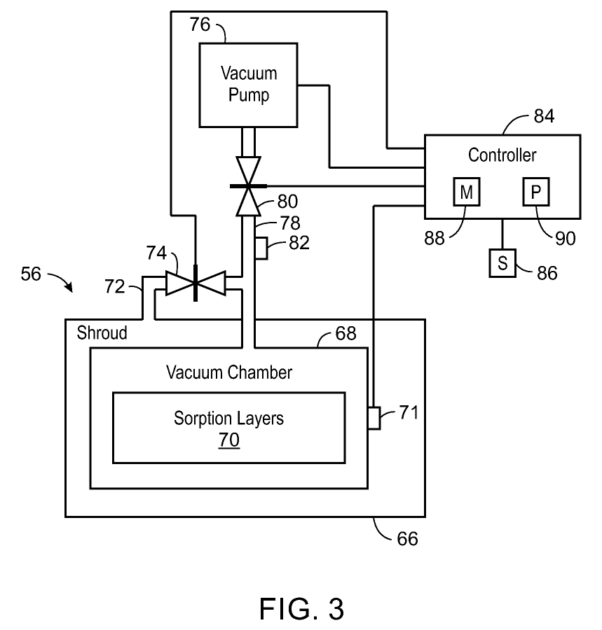

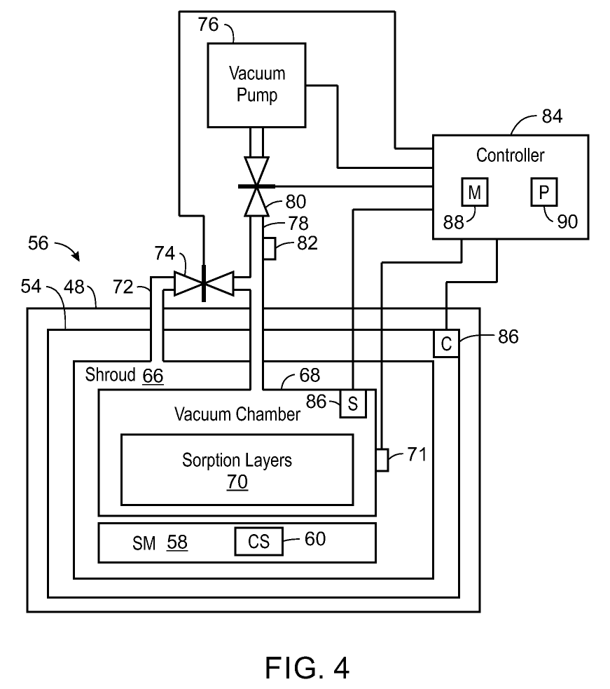

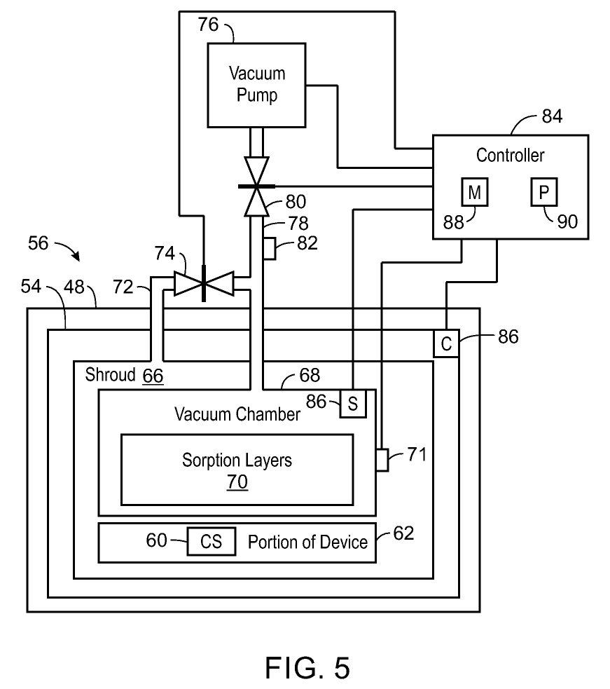

FIG. 3 is a schematic diagram of a cryogenic outgassing management system 56. The cryogenic outgassing management system 56 is configured to collect outgassing gases (e.g., N₂, O₂, H₂, Ar, long hydrocarbon chains, etc.) released from a superconducting machine 58 having a composite structure 60 (e.g., superconducting magnet, superconducting generator, etc.) as depicted in FIG. 4 or a device 62 having a composite structure 60 (e.g., composite cryostat, composite liquid hydrogen tank) as depicted in FIG. 5.

In certain embodiments, the cryogenic outgassing management system 56 includes a shroud 66 configured to be disposed within a vacuum vessel 48 and a thermal shield 54. The shroud 66 is configured to be disposed about the superconducting machine 58 and the composite structure 60 as depicted in FIG. 4 or a portion of the device 62 having the composite structure 60 as depicted in FIG. 5. The shroud 66 is configured to keep the outgassing gases (e.g., generated during a quench event) from contaminating or poisoning a vacuum within the vacuum vessel 48. The shroud 66 is an enclosure configured to keep the outgassing gases from flowing outside the shroud 66 to within the vacuum vessel 48.

The cryogenic outgassing management system 56 also includes a vacuum chamber 68 (e.g., internal baby vacuum chamber). In certain embodiments, the internal vacuum chamber 68 is defined by a wall. The wall may be made of copper, stainless steel, or other low outgassing metal. A plurality of fins (e.g. metal fins) are encompassed by the wall of the vacuum chamber 68. The fins may be coupled (e.g., fastened, welded or glued) to the wall. The fins increase the surface area to adsorb outgassing gases. A plurality of sorption layers 70 may be disposed within the vacuum chamber 68 (e.g., on the fins and/or internal surfaces of the wall). In certain embodiments, the sorption layers 70 include activated carbon or advanced zeolites.

The vacuum chamber 68 is disposed within (encompassed by) the thermal shield 54. In certain embodiments, the vacuum chamber 68 is disposed within (encompassed by) the shroud 66. The vacuum chamber 68 is configured to act as a cryo-pump (via a cryo-sorption effect and vacuum difference between the vacuum vessel 48 and the vacuum chamber 68) to suck outgassing gases (e.g., generated via a quench event) from within the thermal shield 54 and/or the shroud 66 to within the vacuum chamber 68 where the sorption layers 70 initially adsorb the outgassing gases. An electrical heater 71 coupled to or integrated with the wall of the vacuum chamber 68 increases the temperature of the vacuum chamber 68 to release (or desorb) the outgassing gases from the sorption layers 70 to remove the outgassing gases from the vacuum chamber 68 (and to maintain or improve the vacuum level within the vacuum chamber 68) before re-cooldown of the superconducting machine 58.

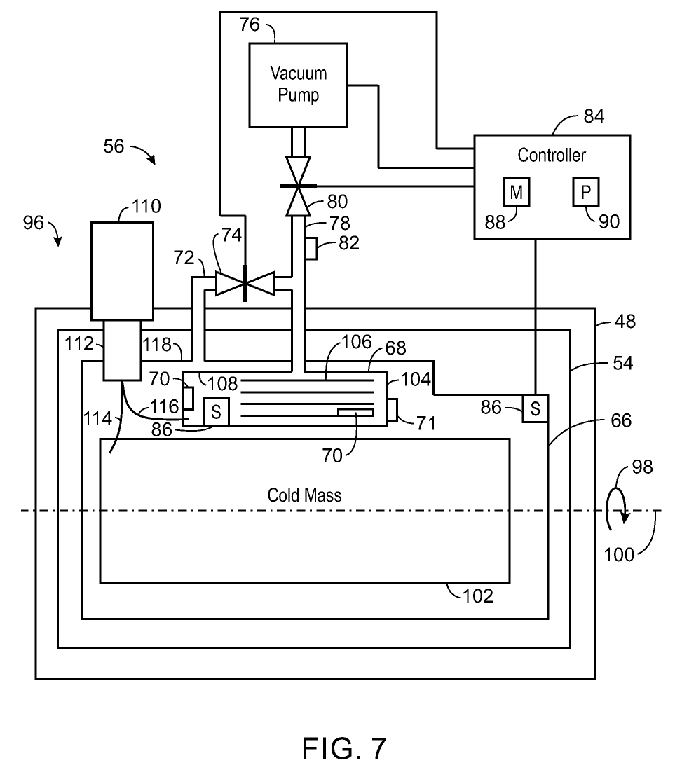

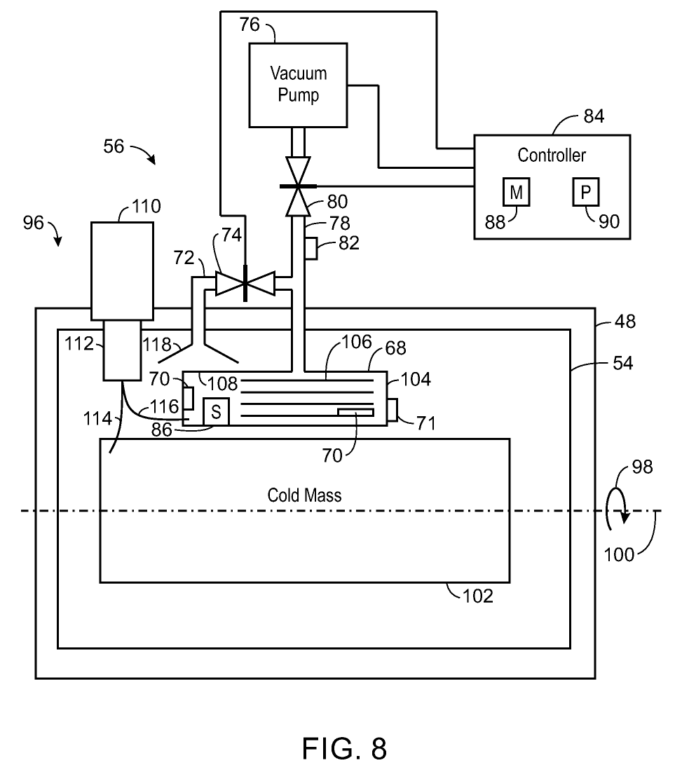

The vacuum chamber 68 is loosely thermally coupled to a cryocooler (e.g., second stage of a cryocooler) via thermal link (see FIGS. 7 and 8). The cryocooler (solely) cools the vacuum chamber 68. No separate cooler (e.g., regular cryo-pump) is utilized to cool the vacuum chamber 68. The thermal link is configured to cool the vacuum chamber 68 to between 5 to 15 K. The vacuum chamber 68 is thermally isolated from the superconducting machine 58. As a result, after a quench event, the temperature of the vacuum chamber 68 should not increase very much. In particular, the warmup of the vacuum chamber 68 is slower than the cryocooler and thermal shield 54 after the quench event and out of cooling. The vacuum chamber 68 is mechanically supported on the superconducting machine 58 through G10 or other thermally non-conductive structural materials.

The cryogenic outgassing management system 56 also includes a first conduit 72 (e.g., piping) coupling an internal atmosphere within the thermal shield 54 and/or the shroud 66 to the vacuum chamber 68. A portion of the first conduit 72 extends through and out of the vacuum vessel 48 and the thermal shield 54 (e.g., from the thermal shield 54 and/or the shroud 66), while another portion of the first conduit 72 extends from outside the vacuum vessel 48 and into and through the vacuum vessel 48 and the thermal shield 54 (e.g. to the vacuum chamber 68). A first valve 74 is disposed along the first conduit 72 outside the vacuum vessel 48. In certain embodiments, the cryogenic outgassing management system 56 includes a vacuum pump 76 located outside the vacuum vessel 48. In certain embodiments, the cryogenic outgassing management system 56 also includes a second conduit 78 coupled to the vacuum pump 76, the first conduit 72, and the vacuum chamber 68 via the first conduit 72. The second conduit 78 is coupled to first conduit 72 between the first valve 74 and the vacuum chamber 68. In certain embodiments, the cryogenic outgassing management system 56 further includes a second valve 80 disposed along the second conduit 78 between the vacuum pump 76 and the vacuum chamber 68. In certain embodiments, a vacuum gauge 82 may be disposed along the first conduit 72 and/or the second conduit 78 to monitor a vacuum level (e.g., within the vacuum chamber 68).

A controller 84 may be communicatively coupled to sensors 86 monitoring a respective temperature within the thermal shield 54 and/or the vacuum chamber 68. The controller 84 is also communicatively coupled to the vacuum gauge 82, the electrical heater 71, and the vacuum pump 76. The controller 84 is communicatively coupled to the first valve 74 and the second valve 80. The controller 84 is configured to provide control signals to actuators of the first valve 74, the second valve 80, the electrical heater 71, and/or the vacuum pump 76 based on feedback (e.g., temperature measurements received from the one or more sensors 86) and/or the vacuum gauge 82. The controller 84 in association with the various sensors and valves 74, 80 acts as a vacuum detection system and/or vacuum valve control/actuation system.

For example, during superconducting machine pumping (e.g., magnet pumping), the first valve 74 is open. The vacuum chamber 68 may also be pumped via the vacuum pump 76. Before starting cooling of the superconducting machine (e.g., magnet), the first valve 74 is closed.

After a magnet quench (in response to a predetermined temperature (e.g., 50 K) and/or a predetermined vacuum level (e.g., 10-4 to 10-5 Torr) being reached), the first valve 74 is automatically opened and the vacuum chamber 68 acts a cryo-pump to suck the outgassing gases from within the thermal shield 54 and/or the shroud 66 (via the first conduit 72) into the vacuum chamber 68) where the vacuum chamber 68 collects the outgassing gases and the sorption layers 70 initially adsorb the outgassing gases. The first valve 74 is closed after the vacuum chamber 68 has warmed to predetermined temperature (e.g., 30 K or higher). After closing the first valve 74 in response to reaching the predetermined temperature, the electrical heater 71 is activated to increase the temperature (e.g., up to 70 K) to desorb the outgassing gases from the sorption surfaces. Also, after closing the first valve 74 in response to reaching the predetermined temperature, the second valve 80 is opened and the vacuum pump 76 is activated to extract the outgassing gases from within the vacuum chamber 68.

The controller 84 includes a memory 88 and a processor 90. The memory 88 may store processor-executable software code or instructions (e.g., firmware or software), which are tangibly stored on a non-transitory computer readable medium. Additionally or alternatively, the memory 88 may store data. As an example, the memory 88 may include a volatile memory, such as random-access memory (RAM), and/or a nonvolatile memory, such as read-only memory (ROM), flash memory, a hard drive, or any other suitable optical, magnetic, or solid-state storage medium, or a combination thereof. Furthermore, the processor 90 may include multiple microprocessors, one or more “general-purpose” microprocessors, one or more special-purpose microprocessors, and/or one or more application specific integrated circuits (ASICS), or some combination thereof. For example, the processor 90 may include one or more reduced instruction set (RISC) or complex instruction set (CISC) processors. The processor 90 executes the software code or instructions stored in the memory 88. The processor 90 may include multiple processors, and/or the memory 88 may include multiple memory devices.

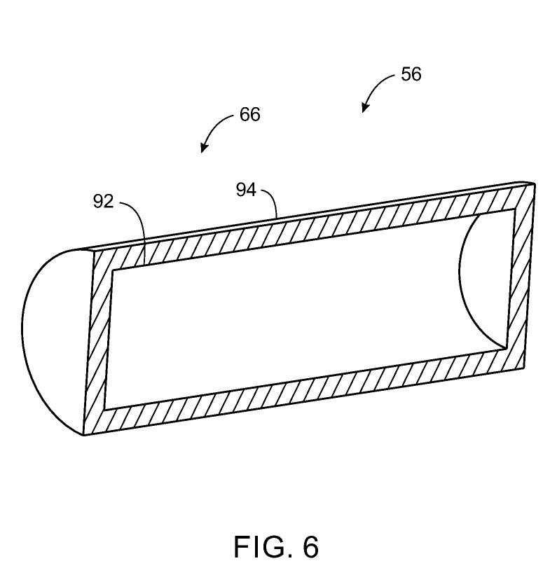

FIG. 6 is a cross-sectional perspective view of the shroud 66 of the cryogenic outgassing management system 56. The shroud 66 includes a shroud body 92. The shroud body 92 may be made of a cryogenically flexible material. In certain embodiments, the shroud body 92 may be made of thin plastic or a compliant polymer. The shroud body 92 includes a shroud covering 94. The shroud covering 94 acts as a vacuum enclosure that does not enable flow of the outgassing gases to the outer vacuum.

FIG. 7 is a cross-sectional view of a superconducting magnet system 96 having the cryogenic outgassing management system 56 in FIG. 3 (e.g., having the shroud 66). In certain embodiments, the superconducting magnet system 96 may be part of an MRI system. The superconducting magnet system 96 having an annular cylindrical shape extends in a circumferential direction 98 about a central axis 100.

The superconducting magnet system 96 includes a cold mass 102 having superconducting magnet coil disposed on a coil composite support structure (e.g., former) (see FIGS. 1 and 2). The shroud 66 of the cryogenic outgassing management system 56 encompasses the cold mass 102. In certain embodiments, the shroud 66 is made of a cryogenically flexible material (e.g., thin plastic or compliant polymer). The shroud 66 is configured to keep the outgassing gases (e.g., generated during a quench event) from contaminating or poisoning a vacuum within the vacuum vessel 48. The shroud 66 is a vacuum enclosure configured to keep the outgassing gases from flowing outside the shroud 66 to within the vacuum vessel 48. The thermal shield 54 encompasses the cold mass 102. A vacuum vessel 48 encompasses the thermal shield 54 and the cold mass 102.

The cryogenic outgassing management system 56 includes the vacuum chamber 68 (e.g., internal baby vacuum chamber) disposed within (encompassed by) the shroud 66. The vacuum chamber 68 is defined by a wall 104. The wall 104 may be made of copper, stainless steel, or other low outgassing metal. A plurality of fins 106 (e.g. metal fins) are encompassed by the wall 104 of the vacuum chamber 68. The fins 106 may be coupled (e.g., fastened, welded or glued) to the wall 104. The fins 106 increase the surface area to adsorb outgassing gases. The number of fins 106 may vary. A plurality of sorption layers 70 may be disposed within the vacuum chamber 68 (e.g., on the fins 106 and/or internal surfaces 108 of the wall 104). In certain embodiments, the sorption layers 70 include activated carbon or advanced zeolites.

The vacuum chamber 68 is configured to act as a cryo-pump (via a cryo-sorption effect and vacuum difference between the vacuum vessel 48 and the vacuum chamber 68) to suck outgassing gases (e.g., generated via a quench event) from within the shroud 66 to within the vacuum chamber 68 where the sorption layers 70 initially adsorb the outgassing gases. An electrical heater 71 coupled to or integrated with the wall 104 of the vacuum chamber 68 increases the temperature of the vacuum chamber 68 to release (or desorb) the outgassing gases from the sorption layers 70 to remove the outgassing gases from the vacuum chamber 68 (and to maintain or improve the vacuum level within the vacuum chamber 68) before re-cooldown of the cold mass 102.

A cryocooler 110 is coupled to (a wall) of the vacuum vessel 48 and the thermal shield 54. A second stage 112 of the cryocooler 110 is thermally coupled to the cold mass 102 via a thermal link 114. The vacuum chamber 68 is loosely thermally coupled to the cryocooler 110 (e.g., second stage 112 of the cryocooler 100) via thermal link 116. The thermal link 114 is more thermally conductive than the thermal link 116. The cryocooler 110 (solely) cools the vacuum chamber 68. No separate cooler (e.g., regular cryo-pump) is utilized to cool the vacuum chamber 68. The thermal link 116 is configured to cool the vacuum chamber 68 to between 5 to 15 K. The vacuum chamber 68 is thermally isolated from the cold mass 102. As a result, after a quench event, the temperature of the vacuum chamber 68 should not increase very much. In particular, the warmup of the vacuum chamber 68 is slower than the cryocooler 110 and thermal shield 54 after the quench event and out of cooling. The vacuum chamber 68 is mechanically supported on the cold mass 102 through G10 or other thermally non-conductive structural materials.

The cryogenic outgassing management system 56 also includes a first conduit 72 (e.g., piping) coupling an internal atmosphere the shroud 66 to the vacuum chamber 68. A portion of the first conduit 72 extends through and out of the vacuum vessel 48 and the thermal shield 54 (e.g., from the thermal shield 54 and/or the shroud 66), while another portion of the first conduit 72 extends from outside the vacuum vessel 48 and into and through the vacuum vessel 48 and the thermal shield 54 (e.g. to the vacuum chamber 68). The first conduit 72 includes a funnel 118 coupled to the shroud 66 for collecting the outgassing gases. A first valve 74 is disposed along the first conduit 72 outside the vacuum vessel 48. In certain embodiments, the cryogenic outgassing management system 56 includes a vacuum pump 76 located outside the vacuum vessel 48. In certain embodiments, the cryogenic outgassing management system 56 also includes a second conduit 78 coupled to the vacuum pump 76, the first conduit 72, and the vacuum chamber 68 via the first conduit 72. The second conduit 78 is coupled to first conduit 72 between the first valve 74 and the vacuum chamber 68. In certain embodiments, the cryogenic outgassing management system 56 further includes a second valve 80 disposed along the second conduit 78 between the vacuum pump 76 and the vacuum chamber 68. In certain embodiments, a vacuum gauge 82 may be disposed along the first conduit 72 and/or the second conduit 78 to monitor a vacuum level (e.g., within the vacuum chamber 68).

A controller 84 may be communicatively coupled to sensors 86 monitoring a respective temperature within the thermal shield 54 and/or the vacuum chamber 68. The controller 84 is also communicatively coupled to the vacuum gauge 82, the electrical heater 71, and the vacuum pump 76. The controller 84 is communicatively coupled to the first valve 74 and the second valve 80. The controller 84 is configured to provide control signals to actuators of the first valve 74, the second valve 80, the electrical heater 71, and/or the vacuum pump 76 based on feedback (e.g., temperature measurements received from the one or more sensors 86) and/or the vacuum gauge 82. The controller 84 in association with the various sensors and valves 74, 80 acts as a vacuum detection system and/or vacuum valve control/actuation system.

For example, during magnet pumping, the first valve 74 is open. The vacuum chamber 68 may also be pumped via the vacuum pump 76. Before starting cooling of the superconducting machine (e.g., magnet), the first valve 74 is closed.

After a magnet quench (in response to a predetermined temperature (e.g., 50 K) and/or a predetermined vacuum level (e.g., 10-4 to 10-5 Torr) being reached), the first valve 74 is automatically opened and the vacuum chamber 68 acts a cryo-pump to suck the outgassing gases from within the shroud 66 (via the first conduit 72) into the vacuum chamber 68) where the vacuum chamber 68 collects the outgassing gases and the sorption layers 70 initially adsorb the outgassing gases. The first valve 74 is closed after the vacuum chamber 68 has warmed to predetermined temperature (e.g., 20 K or 30 K). After closing the first valve 74 in response to reaching the predetermined temperature, the electrical heater 71 is activated to increase the temperature (e.g., up to 70 K) to desorb the outgassing gases from the sorption surfaces. Also, after closing the first valve 74 in response to reaching the predetermined temperature, the second valve 80 is opened and the vacuum pump 76 is activated to extract the outgassing gases from within the vacuum chamber 68.

The controller 84 includes a memory 88 and a processor 90. The memory 88 may store processor-executable software code or instructions (e.g., firmware or software), which are tangibly stored on a non-transitory computer readable medium. Additionally or alternatively, the memory 88 may store data. As an example, the memory 88 may include a volatile memory, such as random-access memory (RAM), and/or a nonvolatile memory, such as read-only memory (ROM), flash memory, a hard drive, or any other suitable optical, magnetic, or solid-state storage medium, or a combination thereof. Furthermore, the processor 90 may include multiple microprocessors, one or more “general-purpose” microprocessors, one or more special-purpose microprocessors, and/or one or more application specific integrated circuits (ASICS), or some combination thereof. For example, the processor 90 may include one or more reduced instruction set (RISC) or complex instruction set (CISC) processors. The processor 90 executes the software code or instructions stored in the memory 88. The processor 90 may include multiple processors, and/or the memory 88 may include multiple memory devices.

FIG. 8 is a cross-sectional view of the superconducting magnet system 96 having cryogenic outgassing management system 56 in FIG. 3 (e.g., lacking a shroud). The superconducting magnet system 96 and the cryogenic outgassing management system 56 are as described in FIG. 7 with a few exceptions. For example, the vacuum chamber 68 is configured to act as a cryo-pump (via a cryo-sorption effect and vacuum difference between the vacuum vessel 48 and the vacuum chamber 68) to suck outgassing gases (e.g., generated via a quench event) from within the thermal shield 54 to within the vacuum chamber 68 where the sorption layers 70 initially adsorb the outgassing gases. The cryogenic outgassing management system 56 also includes the first conduit 72 (e.g., piping) coupling an internal atmosphere within the thermal shield 54 to the vacuum chamber 68. The funnel 118 collects outgassing gases from within the thermal shield 54.

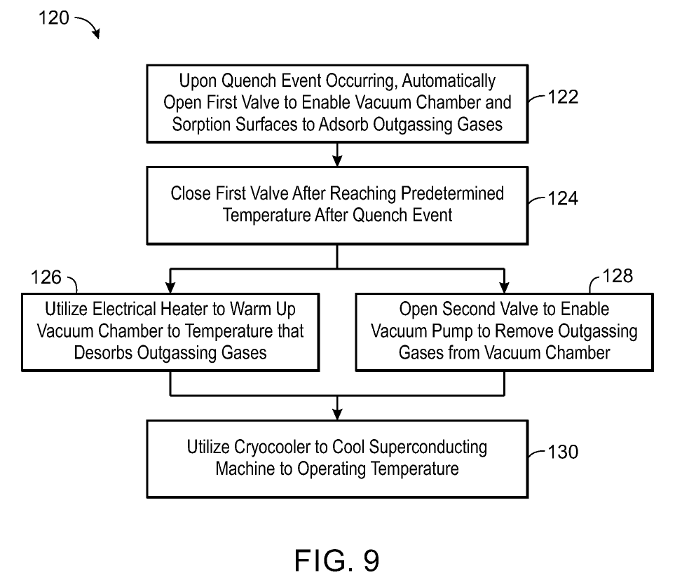

FIG. 9 is a flow chart of a method 120 for managing outgassing from a superconducting machine system (or vacuum management in cryogenic composite environment or maintenance of cryostat vacuum integrity with composite superconducting coils). The superconducting machine system includes a superconducting machine having a composite material (e.g., superconducting electrical machine such as a superconducting magnet of a magnetic resonance imaging system, a superconducting motor, a superconducting generator, etc.). A method similar to the method 120 may be utilized with a device that utilizes composite material (e.g., some composite cryostats, composite liquid hydrogen tanks for aircraft, etc.).

As described above, the superconducting machine system includes a superconducting machine including a composite structure. The superconducting machine system also includes a thermal shield encompassing the superconducting machine. The superconducting machine system further includes a vacuum vessel wall encompassing the thermal shield. The superconducting machine system even further includes a vacuum chamber encompassed by the thermal shield, wherein the vacuum chamber is configured to act as a cryo-pump to adsorb outgassing gases released from the superconducting machine and the composite structure during a quench event. In certain embodiments, the superconducting machine system even further includes a shroud encompassing the both the vacuum chamber and the superconducting machine, wherein the thermal shield encompasses the shroud. The vacuum chamber includes an electrical heater. The superconducting machine system also includes a plurality of sorption surfaces disposed within the vacuum chamber. The superconducting machine system further includes a first conduit coupling an internal atmosphere within the thermal shield to the vacuum chamber. The superconducting machine system even further includes a first valve disposed along the first conduit. The superconducting machine system also includes a vacuum pump located outside the vacuum vessel. The superconducting machine system further includes a second conduit coupled to the vacuum pump, the first conduit, and the vacuum chamber via the first conduit, wherein the second conduit is coupled to first conduit between the first valve and the vacuum chamber. The superconducting machine system further includes a second valve disposed along the second conduit between the vacuum pump and the vacuum chamber.

The method 120 includes (upon the quench event occurring to the superconducting machine system) automatically opening the first valve to enable the vacuum chamber and the plurality of sorption surfaces to adsorb the outgassing gases (from outgassing gases sucked from within thermal shield and/or shroud) (block 122). The automatic opening of the first valve may be occur via control signals (from the controller) provided to actuators of the first valve in response to a predetermined temperature (e.g., 50 K) within the thermal shield and/or a predetermined vacuum level (e.g., 10-4 to 10-5 Torr) within the vacuum chamber being reached. The method 120 also includes closing of the first valve after reaching a predetermined temperature after the quench event (block 124). The closing of the first valve may occur via control signals (from the controller) provided to actuators of the first valve in response to the temperature within the vacuum chamber reaching the predetermined temperature (60 K to 70 K). The method 120 further includes, after closing of the first valve, utilizing the electrical heater (which is activated via controls signals from the controller) to warm up the vacuum chamber to a temperature that desorbs the outgassing gases from the plurality of sorption surfaces (block 126). The method 120 even further includes, after closing of the first valve, opening the second valve to enable the vacuum pump (which is activated via controls signals from the controller) to remove the outgassing gases from within the vacuum chamber (block 128). The method 120 further includes utilizing the cryocooler to cool the superconducting machine to operating temperature (block 130).

Technical effects of the disclosed subject matter include providing for utilization of an internal baby vacuum chamber as a cryo-pump (as part of an outgassing management system) to adsorb outgassing after a magnet quench. Technical effects of the disclosed embodiments include enabling avoiding the use of external cooldown tools in a quench event so that one or more cryocoolers themselves only can cool the superconducting machine (e.g., magnet) back to operating temperature. Technical effects of the disclosed embodiments include avoiding the softening of the vacuum chamber by enabling the capture (and release) of gases that position (e.g., contaminate) the vacuum. Technical effects of the disclosed embodiments include improving sealed magnet serviceability. Technical effects of the disclosed embodiments include maintaining an adequate magnet vacuum level to enable faster re-cooldown of the magnet after magnet quench. This is particularly important and beneficial to a sealed magnet without helium vessel. Removing the helium vessel of the sealed magnet can save cost and minimize heat load from magnet gradient interaction(MGI).

The disclosure also provides support for a superconducting machine system, comprising: a superconducting machine comprising a composite structure; a thermal shield encompassing the superconducting machine; a vacuum vessel encompassing the thermal shield; and a vacuum chamber encompassed by the thermal shield, wherein the vacuum chamber is configured to act as a cryo-pump to adsorb outgassing gases released from the superconducting machine and the composite structure during a quench event. In a first example of the superconducting machine system, the vacuum chamber is configured to utilize a difference in vacuum pressure between the vacuum vessel and the vacuum chamber in conjunction with cryo-sorption effect to adsorb the outgassing gases. In a second example of the superconducting machine system, optionally including the first example, the superconducting machine system further comprises: a first conduit coupling an internal atmosphere within the thermal shield to the vacuum chamber; and a first valve disposed along the first conduit. In a third example of the superconducting machine system, optionally including one or both of the first and second examples, the first valve is configured to be closed prior to cooling of the superconducting machine, and the first valve is configured to be automatically opened after a quench event to enable the vacuum chamber to adsorb the outgassing gases. In a fourth example of the superconducting machine system, optionally including one or more of each of the first through third examples, the vacuum chamber comprises a plurality of sorption surfaces disposed within the vacuum chamber to initially adsorb the outgassing gases. In a fifth example of the superconducting machine system, optionally including one or more of each of the first through fourth examples, the vacuum chamber comprises a plurality of fins, and the plurality of sorption surfaces are disposed on the plurality of fins and/or internal wall surfaces of the vacuum chamber. In a sixth example of the superconducting machine system, optionally including one or more of each of the first through fifth examples, the plurality of sorption surfaces comprises activated carbon or advanced zeolites. In a seventh example of the superconducting machine system, optionally including one or more of each of the first through sixth examples, the superconducting machine system further comprises an electrical heater disposed on the vacuum chamber, wherein the first valve is configured to be closed after reaching a predetermined temperature after the quench event, and the electrical heater, after closing of the first valve, is configured to warm up the vacuum chamber to a temperature that desorbs the outgassing gases from the plurality of sorption surfaces. In an eighth example of the superconducting machine system, optionally including one or more of each of the first through seventh examples, the superconducting machine system further comprises: a vacuum pump located outside the vacuum vessel; a second conduit coupled to the vacuum pump, the first conduit, and the vacuum chamber via the first conduit, wherein the second conduit is coupled to first conduit between the first valve and the vacuum chamber; and a second valve disposed along the second conduit between the vacuum pump and the vacuum chamber. In a ninth example of the superconducting machine system, optionally including one or more of each of the first through eighth examples, the second valve is configured, after closing of the first valve, to be opened to enable the vacuum pump to remove the outgassing gases that were desorbed from the plurality of sorption surfaces. In a tenth example of the superconducting machine system, optionally including one or more of each of the first through ninth examples, the superconducting machine system further comprises a shroud encompassing the superconducting machine, wherein the thermal shield encompasses the shroud, and the shroud encompasses the vacuum chamber, wherein the shroud is configured to keep the outgassing gases from flowing outside the shroud. In an eleventh example of the superconducting machine system, optionally including one or more of each of the first through tenth examples, the superconducting machine comprises a superconducting magnet coil disposed on a support structure, and the support structure comprises the composite structure. In a twelfth example of the superconducting machine system, optionally including one or more or each of the first through eleventh examples, the vacuum chamber is thermally isolated from the thermal shield and the superconducting machine. In a thirteenth example of the superconducting machine system, optionally including one or more or each of the first through twelfth examples, the superconducting machine system further comprises a cryocooler coupled to the vacuum vessel and the thermal shield, wherein the vacuum chamber is thermally coupled to the cryocooler via a thermal link, and the cryocooler is configured to cool the vacuum chamber. In a fourteenth example of the superconducting machine system, optionally including one or more or each of the first through thirteenth examples, the cryocooler is configured to cool the vacuum chamber to a temperature between 5 and 15 Kelvin, and wherein the vacuum chamber is solely cooled by the cryocooler.

The disclosure also provides support for a superconducting magnet system for a magnetic resonance imaging system, comprising: a superconducting magnet coil disposed on a support structure, wherein the support structure comprises a composite material; a thermal shield encompassing the superconducting magnet coil and the support structure; a vacuum vessel encompassing the thermal shield; and a vacuum chamber encompassed by the thermal shield, wherein the vacuum chamber is configured to act as a cryo-pump to adsorb outgassing gases released from the superconducting magnet coil and the support structure during a quench event. In a first example of the superconducting magnet system, the vacuum chamber is thermally isolated from the thermal shield and the superconducting machine. In a second example of the superconducting magnet system, optionally including the first example, the superconducting magnet system further comprises a cryocooler coupled to the vacuum vessel and the thermal shield, wherein the vacuum chamber is thermally coupled to the cryocooler via a thermal link, and the cryocooler is configured to cool the vacuum chamber. In a third example of the superconducting magnet system, optionally including one or both of the first and second examples, further comprising a shroud encompassing the superconducting machine, wherein the thermal shield encompasses the shroud, and the shroud encompasses the vacuum chamber, wherein the shroud is configured to keep the outgassing gases from flowing outside the shroud.

The disclosure also provides support for a method for managing outgassing from a superconducting machine system, comprising: for the superconducting machine system, comprising: a superconducting machine comprising a composite structure; a thermal shield encompassing the superconducting machine; a vacuum vessel encompassing the thermal shield; a vacuum chamber encompassed by the thermal shield, wherein the vacuum chamber is configured to act as a cryo-pump to adsorb outgassing gases released from the superconducting machine and the composite structure during a quench event; and the vacuum chamber comprises an electrical heater; a plurality of sorption surfaces disposed within the vacuum chamber; a first conduit coupling an internal atmosphere within the thermal shield to the vacuum chamber; a first valve disposed along the first conduit; a vacuum pump located outside the vacuum vessel; and a second conduit coupled to the vacuum pump, the first conduit, and the vacuum chamber via the first conduit, wherein the second conduit is coupled to first conduit between the first valve and the vacuum chamber; and a second valve disposed along the second conduit between the vacuum pump and the vacuum chamber; upon the quench event occurring to the superconducting machine system, the method comprises: automatically opening the first valve to enable the vacuum chamber and the plurality of sorption surfaces to adsorb the outgassing gases; closing the first valve after reaching a predetermined temperature after the quench event; after closing of the first valve, utilize the electrical heater to warm up the vacuum chamber to a temperature that desorbs the outgassing gases from the plurality of sorption surfaces; and after closing of the first valve, opening the second valve to enable the vacuum pump to remove the outgassing gases from within the vacuum chamber.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function]…” or “step for [perform]ing [a function]…”, it is intended that such elements are to be interpreted under 35 U.S.C. 112(f). However, for any claims containing elements designated in any other manner, it is intended that such elements are not to be interpreted under 35 U.S.C. 112(f).

This written description uses examples to disclose the present subject matter, including the best mode, and also to enable any person skilled in the art to practice the subject matter, including making and using any devices or systems and performing any incorporated methods. The patentable scope of the subject matter is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

1. A superconducting machine system, comprising:
a superconducting machine comprising a composite structure;
a thermal shield encompassing the superconducting machine;
a vacuum vessel encompassing the thermal shield; and
a vacuum chamber encompassed by the thermal shield, wherein the vacuum chamber is configured to act as a cryo-pump to adsorb outgassing gases released from the superconducting machine and the composite structure during a quench event.

2. The superconducting machine system of claim 1, wherein the vacuum chamber is configured to utilize a difference in vacuum pressure between the vacuum vessel and the vacuum chamber in conjunction with cryo-sorption effect to adsorb the outgassing gases.

3. The superconducting machine system of claim 1, further comprising:
a first conduit coupling an internal atmosphere within the thermal shield to the vacuum chamber; and
a first valve disposed along the first conduit.

4. The superconducting machine system of claim 3, wherein the first valve is configured to be closed prior to cooling of the superconducting machine, and the first valve is configured to be automatically opened after a quench event to enable the vacuum chamber to adsorb the outgassing gases.

5. The superconducting machine system of claim 4, wherein the vacuum chamber comprises a plurality of sorption surfaces disposed within the vacuum chamber to initially adsorb the outgassing gases.

6. The superconducting machine system of claim 5, wherein the vacuum chamber comprises a plurality of fins, and the plurality of sorption surfaces are disposed on the plurality of fins and/or internal wall surfaces of the vacuum chamber.

7. The superconducting machine system of claim 6, wherein the plurality of sorption surfaces comprises activated carbon or advanced zeolites.

8. The superconducting machine system of claim 5, further comprising an electrical heater disposed on the vacuum chamber, wherein the first valve is configured to be closed after reaching a predetermined temperature after the quench event, and the electrical heater, after closing of the first valve, is configured to warm up the vacuum chamber to a temperature that desorbs the outgassing gases from the plurality of sorption surfaces.

9. The superconducting machine system of claim 8, further comprising:
a vacuum pump located outside the vacuum vessel;
a second conduit coupled to the vacuum pump, the first conduit, and the vacuum chamber via the first conduit, wherein the second conduit is coupled to first conduit between the first valve and the vacuum chamber; and
a second valve disposed along the second conduit between the vacuum pump and the vacuum chamber.

10. The superconducting machine system of claim 9, wherein the second valve is configured, after closing of the first valve, to be opened to enable the vacuum pump to remove the outgassing gases that were desorbed from the plurality of sorption surfaces.

11. The superconducting machine system of claim 3, further comprising a shroud encompassing the superconducting machine, wherein the thermal shield encompasses the shroud, and the shroud encompasses the vacuum chamber, wherein the shroud is configured to keep the outgassing gases from flowing outside the shroud.

12. The superconducting machine system of claim 1, wherein the superconducting machine comprises a superconducting magnet coil disposed on a support structure, and the support structure comprises the composite structure.

13. The superconducting machine system of claim 1, wherein the vacuum chamber is thermally isolated from the thermal shield and the superconducting machine.

14. The superconducting machine system of claim 13, further comprising a cryocooler coupled to the vacuum vessel and the thermal shield, wherein the vacuum chamber is thermally coupled to the cryocooler via a thermal link, and the cryocooler is configured to cool the vacuum chamber.

15. The superconducting machine system of claim 14, wherein the cryocooler is configured to cool the vacuum chamber to a temperature between 5 and 15 Kelvin, and wherein the vacuum chamber is solely cooled by the cryocooler.

16. A superconducting magnet system for a magnetic resonance imaging system, comprising:
a superconducting magnet coil disposed on a support structure, wherein the support structure comprises a composite material;
a thermal shield encompassing the superconducting magnet coil and the support structure;
a vacuum vessel encompassing the thermal shield; and
a vacuum chamber encompassed by the thermal shield, wherein the vacuum chamber is configured to act as a cryo-pump to adsorb outgassing gases released from the superconducting magnet coil and the support structure during a quench event.

17. The superconducting magnet system of claim 16, wherein the vacuum chamber is thermally isolated from the thermal shield and the superconducting machine.

18. The superconducting magnet system of claim 17, further comprising a cryocooler coupled to the vacuum vessel and the thermal shield, wherein the vacuum chamber is thermally coupled to the cryocooler via a thermal link, and the cryocooler is configured to cool the vacuum chamber.

19. The superconducting magnet system of claim 16, further comprising a shroud encompassing the superconducting machine, wherein the thermal shield encompasses the shroud, and the shroud encompasses the vacuum chamber, wherein the shroud is configured to keep the outgassing gases from flowing outside the shroud.

20. A method for managing outgassing from a superconducting machine system, comprising:
for the superconducting machine system, comprising:
a superconducting machine comprising a composite structure;
a thermal shield encompassing the superconducting machine;
a vacuum vessel encompassing the thermal shield;
a vacuum chamber encompassed by the thermal shield, wherein the vacuum chamber is configured to act as a cryo-pump to adsorb outgassing gases released from the superconducting machine and the composite structure during a quench event; and the vacuum chamber comprises an electrical heater;
a plurality of sorption surfaces disposed within the vacuum chamber;
a first conduit coupling an internal atmosphere within the thermal shield to the vacuum chamber;
a first valve disposed along the first conduit;
a vacuum pump located outside the vacuum vessel; and
a second conduit coupled to the vacuum pump, the first conduit, and the vacuum chamber via the first conduit, wherein the second conduit is coupled to first conduit between the first valve and the vacuum chamber; and
a second valve disposed along the second conduit between the vacuum pump and the vacuum chamber;
upon the quench event occurring to the superconducting machine system, the method comprises:
automatically opening the first valve to enable the vacuum chamber and the plurality of sorption surfaces to adsorb the outgassing gases;
closing the first valve after reaching a predetermined temperature after the quench event;
after closing of the first valve, utilize the electrical heater to warm up the vacuum chamber to a temperature that desorbs the outgassing gases from the plurality of sorption surfaces; and
after closing of the first valve, opening the second valve to enable the vacuum pump to remove the outgassing gases from within the vacuum chamber.
